(19) United States
(12) Patent Application Publication
(10) Pub. No.: US 2026/0352176 A1
(43) Pub. Date: Nov. 5, 2026

(54) MULTILAYERED COMMON MODE FILTER

(71) Applicant: AMOTECH CO., LTD., Incheon (KR)

(72) Inventor: Byungguk LIM, Incheon (KR)

(73) Assignee: AMOTECH CO., LTD., Incheon (KR)

(21) Appl. No.: 19/116,274

(22) PCT Filed: Sep. 6, 2023
(86) PCT No.: PCT/KR2023/013343

§ 371 Date: Mar. 27, 2025

(30) Foreign Application Priority Data
Sep. 27, 2022 (KR) 10-2022-0122183

(51) Int. Cl. H03H 7/42; H03H 1/00; H03H 7/01

(52) U.S. Cl. CPC H03H 7/427; H03H 1/00; H03H 7/0153; H03H 7/1783; H03H 2001/0085

(57) ABSTRACT

Disclosed is a multilayered common mode filter having first and second capacitance layers arranged on the top and bottom surfaces, respectively, of an electrode layer provided with a plurality of coil patterns that form two channels. The disclosed multilayered common mode filter comprises first and second capacitance layers, symmetric with an electrode layer interposed therebetween, wherein the first and second capacitance layers are in the form of ground patterns and capacitor patterns stacked in alternation, and, along with a pole formed by the coil patterns, an additional pole is formed by the capacitance layers and coil patterns to exhibit wideband characteristics.

### TECHNICAL FIELD

The present disclosure relates to a multilayered common mode filter that allows signal current in a differential mode to pass through and removes noise current in a common mode in an electronic device to which a high-speed signal line is applied.

### BACKGROUND ART

Generally, mobile terminals adopt the Mobile Industry Processor Interface (MIPI) D-PHY standard as a digital data transmission standard. The MIPI D-PHY standard is a digital data transmission standard that connects a main circuit of a mobile terminal to a display or camera, and refers to a method of transmitting data using a differential signal with a plurality of transmission lines.

With the rapid increase in the volume of data transmitted and received within mobile terminals, a transmission method capable of transmitting and receiving data at a higher speed than the MIPI D-PHY standard is required for mobile terminals.

Accordingly, recent research in the mobile terminal industry has been conducted on applying the MIPI C-PHY standard to mobile terminals. The MIPI C-PHY standard employs a plurality of transmission lines, transmitting different voltages to the respective transmission lines from a transmitting side and performing differential output on a receiving side by taking differences between the lines.

The contents described in the Background Art are to aid in understanding the background of the disclosure, and may include contents that are not related to disclosed conventional technology.

### SUMMARY OF INVENTION

### Technical Problem

The present disclosure is proposed in consideration of the circumstances, and an object of the present disclosure is to provide a multilayered common mode filter in which capacitance layers are respectively placed over and under an electrode layer so as to implement a broadband characteristic and allow resistance and inductance of coil patterns forming each channel to be uniformly formed.

### Solution to Problem

To achieve the above object, a multilayered common mode filter according to an embodiment of the present disclosure may include a filter stack formed by stacking an electrode layer, a first capacitance layer, and a second capacitance layer, the filter stack including an upper surface, a lower surface, a first side surface, a second side surface opposite to the first side surface, a third side surface, and a fourth side surface opposite to the third side surface. The electrode layer may include a stack provided with a plurality of coil patterns. The first capacitance layer may include a stack provided with a capacitor pattern and a ground pattern, and may be disposed over the electrode layer. The second capacitance layer may include a stack provided with a capacitor pattern and a ground pattern, and may be disposed under the electrode layer. The first capacitance layer and the second capacitance layer may each be configured such that the capacitor pattern overlaps at least one of the plurality of coil patterns and forms an additional capacitance.

The electrode layer may include a first sheet, a first coil pattern disposed on a first surface of the first sheet, a second sheet disposed under the first sheet, a second coil pattern disposed on a first surface of the second sheet, a third sheet interposed between the first sheet and the second sheet, a third coil pattern disposed on a first surface of the third sheet, a fourth sheet interposed between the second sheet and the third sheet, and a fourth coil pattern disposed on a first surface of the fourth sheet. A first end of the first coil pattern may be connected to a first end of the second coil pattern through a first via hole, and a second end of the first coil pattern may be exposed to the second side surface of the filter stack. The first end of the second coil pattern may be connected to the first end of the first coil pattern through the first via hole, and a second end of the second coil pattern may be exposed to the first side surface of the filter stack opposite to one side surface of the filter stack. A first end of the third coil pattern may be connected to a first end of the fourth coil pattern through a second via hole, and a second end of the third coil pattern may be exposed to the first side surface of the filter stack. The first end of the fourth coil pattern may be connected to the first end of the first coil through the first via hole, and a second end of the fourth coil pattern may be exposed to the second side surface of the filter stack opposite to the first side surface of the filter stack.

The first end of the first coil pattern may be connected to the first end of the second coil pattern through the first via hole passing through the first sheet, the third sheet, and the fourth sheet. The first coil pattern and the second coil pattern may be connected through the first via hole and form a first coil forming a first channel. The first end of the third coil pattern may be connected to the first end of the fourth coil pattern through the second via hole passing through the third sheet. The third coil pattern and the fourth coil pattern may be connected through the second via hole and form a second coil forming a second channel.

The capacitor pattern and the ground pattern of the first capacitance layer may be configured to be symmetrical with the capacitor pattern and the ground pattern of the second capacitance layer with the electrode layer interposed therebetween.

The first capacitance layer and the second capacitance layer may each be configured as a stack formed by alternately stacking N fifth sheets and N sixth sheets, A plurality of capacitor patterns may be disposed on each of the fifth sheets. A ground pattern may be disposed on each of the sixth sheets. The first capacitance layer may be configured such that the six sheets are stacked over the fifth sheets, so that one of the six sheets is disposed at an uppermost portion of the first capacitance layer, and one of the fifth sheets is disposed at a lowermost portion of the first capacitance layer. The second capacitance layer may be configured such that the fifth sheets are stacked over the sixth sheets, so that one of the fifth sheets is disposed at an uppermost portion of the second capacitance layer, and one of the sixth sheets is disposed at a lowermost portion of the second capacitance layer.

The first capacitance layer and the second capacitance layer may each be configured as a stack formed by alternately stacking N fifth sheets and N+1 sixth sheets, A plurality of capacitor patterns may be disposed on each of the fifth sheets. A ground pattern may be disposed on each of the sixth sheets. The first capacitance layer and the second capacitance layer may each be configured such that one of the fifth sheets is interposed between every two adjacent ones of the sixth sheets. One of the sixth sheets may be disposed at both an uppermost portion and a lowermost portion of each of the first capacitance layer and the second capacitance layer.

The capacitor pattern may include a first capacitor pattern disposed on a first surface of a fifth sheet, a second capacitor pattern disposed on the first surface of the fifth sheet, and disposed to be spaced apart from the first capacitor pattern, a third capacitor pattern disposed on the first surface of the fifth sheet, and disposed to be spaced apart from the first capacitor pattern and the second capacitor pattern, and a fourth capacitor pattern disposed on the first surface of the fifth sheet, and disposed to be spaced apart from the first to third capacitor patterns. A first end of the first capacitor pattern may be disposed to face a first end of the third capacitor pattern. A first end of the second capacitor pattern may be disposed to face a first end of the fourth capacitor pattern. A second end of the first capacitor pattern and a second end of the second capacitor pattern may be exposed to the first side surface of the filter stack. A second end of the third capacitor pattern and a second end of the fourth capacitor pattern may be exposed to the second side surface of the filter stack.

The ground pattern may include a first pattern having a planar shape and disposed on a first surface of a sixth sheet, a second pattern disposed on the first surface of the sixth sheet, and a third pattern disposed on the first surface of the sixth sheet. A first end of the second pattern may be connected to one edge of the first pattern, and a second end of the second pattern may be exposed to the third side surface of the filter stack. A first end of the third pattern may be connected to another edge of the first pattern opposite to the one edge of the first pattern, and a second end of the third pattern may be exposed to the fourth side surface of the filter stack.

The multilayered common mode filter according to an embodiment of the present disclosure may further include a first external electrode disposed on the second side surface of the filter stack opposite to the first side surface of the filter stack, and connected to a first coil pattern exposed to the second side surface of the filter stack, a second external electrode disposed on the second side surface of the filter stack, and connected to a fourth coil pattern exposed to the second side surface of the filter stack, a third external electrode disposed on the first side surface of the filter stack, and connected to a second coil pattern exposed to the first side surface of the filter stack, and a fourth external electrode disposed on the first side surface of the filter stack, and connected to a third coil pattern exposed to the first side surface of the filter stack. The first external electrode may be further connected to a third capacitor pattern exposed to the second side surface of the filter stack. The second external electrode may be further connected to a fourth capacitor pattern exposed to the second side surface of the filter stack. The third external electrode may be further connected to a first capacitor pattern exposed to the first side surface of the filter stack. The fourth external electrode may be further connected to a second capacitor pattern exposed to the first side surface of the filter stack.

The multilayered common mode filter according to an embodiment of the present disclosure may further include a fifth external electrode disposed on the third side surface of the filter stack, and connected to a second pattern of the ground pattern, the second pattern being exposed to the third side surface of the filter stack, and a sixth external electrode disposed on the fourth side surface of the filter stack opposite to the third side surface of the filter stack, and connected to a third pattern of the ground pattern, the third pattern being exposed to the fourth side surface of the filter stack.

### Advantageous Effects of Invention

According to the present disclosure, a multilayered common mode filter has an effect of allowing a distance (spacing) between coil patterns forming each channel to be kept constant, thereby enabling resistance and inductance of the coil patterns forming each channel to remain uniform.

Furthermore, the multilayered common mode filter is configured such that capacitance layers are disposed on an upper portion and a lower portion of an electrode stack, thereby forming an additional notch in a common mode attenuation characteristic, thus exhibiting an effect of expanding an attenuation band.

In addition, the multilayered common mode filter has an effect of implementing a broadband characteristic by forming an additional pole (that is, additional capacitance) using the capacitance layers and the coil patterns, together with a pole formed by the coil patterns of the electrode stack.

Furthermore, the multilayered common mode filter has an effect of minimizing variation in inductance characteristics of the coil patterns by forming a constant distance (spacing) between the channels.

Furthermore, the multilayered common mode filter has an effect of enhancing magnetic coupling (i.e., electromagnetic coupling) between a first coil and a second coil, and minimizing degradation of a differential signal.

### BRIEF DESCRIPTION OF DRAWINGS

FIG. 1 is a perspective view of a multilayered common mode filter according to an embodiment of the present disclosure.

FIG. 2 is a perspective view for describing a filter stack in FIG. 1.

FIGS. 3 to 7 are exploded perspective views for describing an example of an electrode layer of FIG. 2.

FIGS. 8 to 12 are diagrams for explaining a first capacitance layer and a second capacitance layer of FIG. 2.

FIG. 13 is a diagram for explaining a change in frequency characteristics depending on a change in a stacked structure of a capacitance layer of a multilayered common mode filter according to an embodiment of the present disclosure.

FIG. 14 is a diagram illustrating an equivalent circuit of the multilayered common mode filter according to an embodiment of the disclosure.

FIG. 15 is a diagram for explaining frequency characteristics of the multilayered common mode filter according to an embodiment of the disclosure.

### DESCRIPTION OF EMBODIMENT

Hereinafter, embodiments of the present disclosure will be described in detail with reference to the attached drawings.

Embodiments are provided to explain the present disclosure more fully to a person having ordinary knowledge in the art to which the present disclosure pertains. The following embodiments may be modified in various other forms, and the scope of the present disclosure is not limited to the following embodiments. Rather, these embodiments are provided to make the present disclosure more thorough and complete and to fully convey the spirit of the present disclosure.

Terms used in this specification are used to describe a specific embodiment, and are not intended to limit the present disclosure. Furthermore, in this specification, an expression of the singular number may include an expression of the plural number unless clearly defined otherwise in the context.

In the description of embodiments, when it is described that each layer (film), area, pattern, or structure is formed “on” or “under” each substrate, layer (film), area, pad, or pattern, this includes both expressions, including that a layer is formed on another layer “directly” or “with an additional layer interposed between the two layers (indirectly)”. Furthermore, the criterion for “on” or “under” of each layer is based on the drawings.

The drawings are provided solely to aid in understanding the spirit of the present disclosure and should not be interpreted as limiting the scope of the present disclosure. Furthermore, in the drawings, relative thickness, length, or size may be exaggerated for convenience and clarity of description.

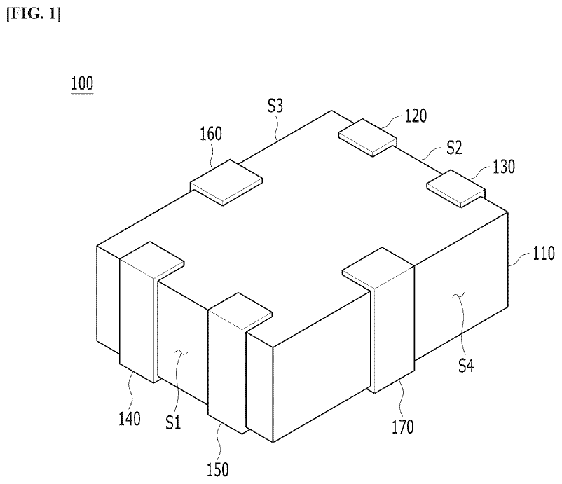

Referring to FIG. 1, a multilayered common mode filter 100 according to an embodiment of the present disclosure includes a filter stack 110, a first external electrode 120, a second external electrode 130, a third external electrode 140, a fourth external electrode 150, a fifth external electrode 160, and a sixth external electrode 170. Here, the multilayered common mode filter operates, as an example, as a two-channel C-PHY common mode filter.

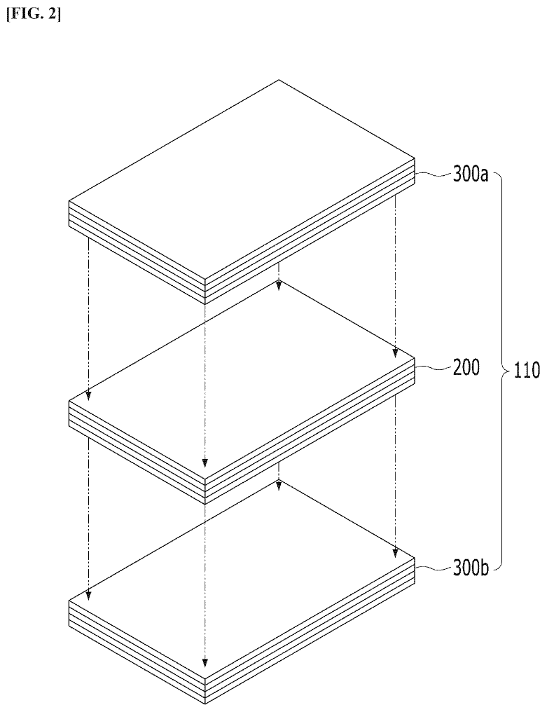

Referring to FIG. 2, the filter stack 110 is a stack in which an electrode layer 200, a first capacitance layer 300a, and a second capacitance layer 300b are stacked.

The electrode layer 200 is configured as a stack in which a plurality of coil patterns are formed. A magnetic layer formed of ferrite or the like may be further placed over the electrode layer 200.

The electrode layer 200 is configured by stacking a plurality of sheets in which the coil patterns are respectively formed. The coil patterns formed on the plurality of sheets form different channels.

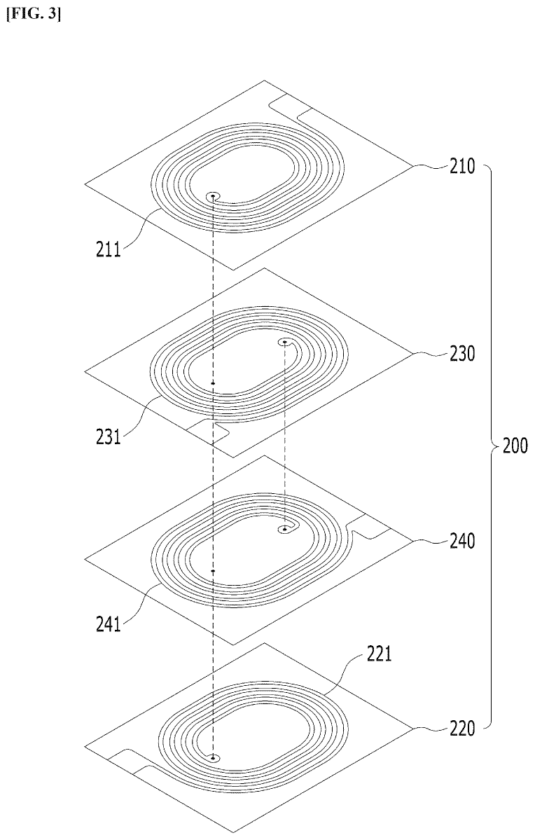

Referring to FIG. 3, the electrode layer 200 is configured by stacking the plurality of sheets in which the coil patterns are respectively formed, and includes a first sheet 210, a second sheet 220 disposed below the first sheet 210, a third sheet 230 interposed between the first sheet 210 and the second sheet 220, and a fourth sheet 240 interposed between the second sheet 220 and the third sheet 230.

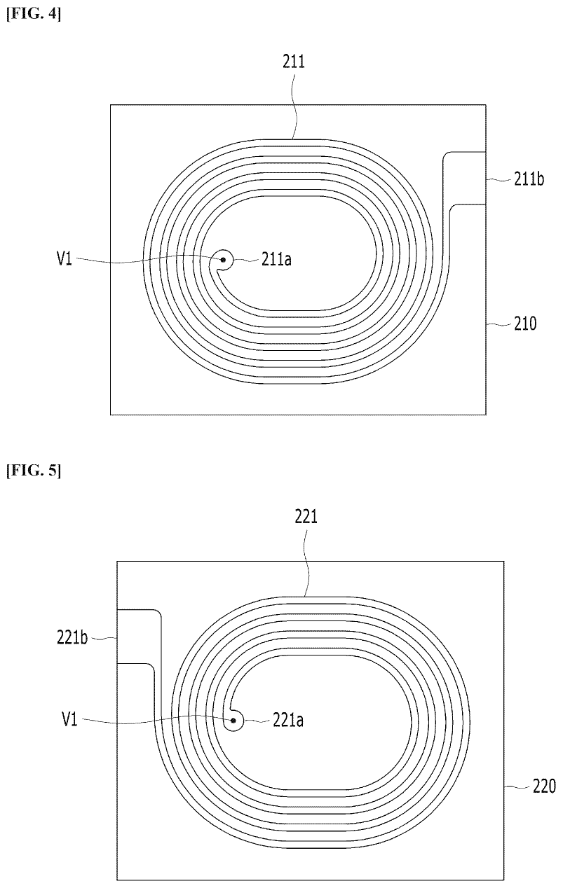

Referring to FIG. 4, the first sheet 210 is disposed on an uppermost portion of the electrode layer 200. A first coil pattern 211, which forms a first channel, is disposed on the first sheet 210.

The first coil pattern 211 is disposed on an upper surface of the first sheet 210. The first coil pattern 211 forms a loop that is wound multiple times around a center of the first sheet 210.

A first end 211a of the first coil pattern 211 is located adjacent to the center of the first sheet 210. The first end 211a of the first coil pattern 211 is connected to the coil pattern formed on the second sheet 220 through a first via hole V1.

The first via hole V1 is adjacent to the center of the first sheet 210 and is positioned at the first end 211a of the first coil pattern 211. The first via hole V1 is formed to pass through the first sheet 210, the third sheet 230, and the fourth sheet 240, thereby allowing connection of the first coil pattern 211 to the coil pattern formed on the second sheet 220.

A second end 211b of the first coil pattern 211 is disposed to be aligned with a second edge of the first sheet 210, which is opposite to a first edge of the first sheet 210. Accordingly, the second end 211b of the first coil pattern 211 is exposed to a second side surface S2 of the filter stack 110. Here, the second side surface S2 of the filter stack 110 is a side surface opposite to a first side surface S1 of the filter stack 110.

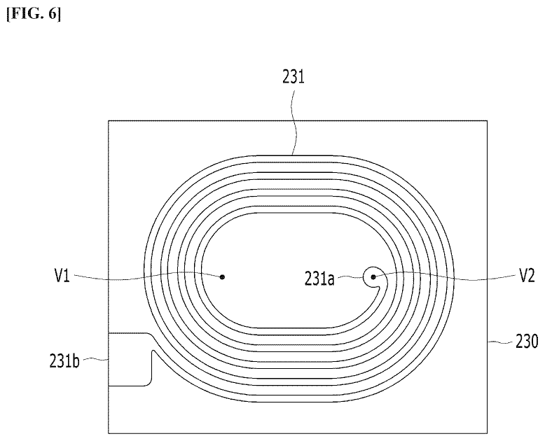

Referring to FIG. 5, the second sheet 220 is disposed below the first sheet 210. A second coil pattern 221, which constitutes the first channel together with the first coil pattern 211 of the first sheet 210, is disposed on the second sheet 220.

The second coil pattern 221 is disposed on an upper surface of the second sheet 220. The second coil pattern 221 forms a loop that is wound multiple times around a center of the second sheet 220.

A first end 221a of the second coil pattern 221 is located adjacent to the center of the second sheet 220. The first end 221a of the second coil pattern 221 is connected to the first end 211a of the first coil pattern 211 formed on the first sheet 210 through the first via hole V1. Accordingly, the first coil pattern 211 and the second coil pattern 221 constitute the first channel.

A second end 221b of the second coil pattern 221 is disposed to be aligned with a first edge of the second sheet 220. Hence, the second end 221b of the second coil pattern 221 is exposed to the first side surface S1 of the filter stack 110.

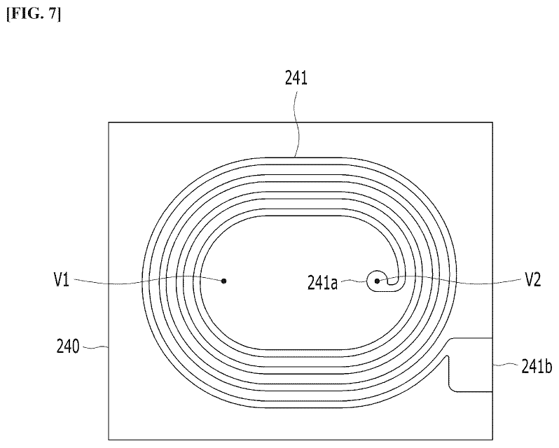

Referring to FIG. 6, the third sheet 230 is interposed between the first sheet 210 and the second sheet 220. A third coil pattern 231, which forms a second channel, is disposed on the third sheet 230.

The third coil pattern 231 is disposed on an upper surface of the third sheet 230. The third coil pattern 231 forms a loop that is wound multiple times around a center of the third sheet 230.

A first end 231a of the third coil pattern 231 is disposed adjacent to the center of the third sheet 230. The first end 231a of the third coil pattern 231 is connected to the coil pattern formed on the fourth sheet 240 through a second via hole V2.

The second via hole V2 is adjacent to the center of the third sheet 230 and is positioned at the first end 231a of the third coil pattern 231. The second via hole V2 is formed to pass through the third sheet 230, thereby allowing connection of the third coil pattern 231 to the coil pattern formed on the fourth sheet 240.

A second end 231b of the third coil pattern 231 is disposed to be aligned with a first edge of the third sheet 230. Hence, the second end 231b of the third coil pattern 231 is exposed to the first side surface of the filter stack 110.

The first via hole V1, spaced apart from the first end 231a of the third coil pattern 231, is formed in the third sheet 230. The first via hole V1 formed in the third sheet 230 connects the first via hole V1 formed in the fourth sheet 240 and the first end 211a of the first coil pattern 211.

Referring to FIG. 7, the fourth sheet 240 is disposed under the third sheet 230 and is interposed between the second sheet 220 and the third sheet 230. A fourth coil pattern 241, which constitutes the second channel together with the third coil pattern 231, is disposed on the fourth sheet 240.

The fourth coil pattern 241 is disposed on an upper surface of the fourth sheet 240. The fourth coil pattern 241 forms a loop that is wound multiple times around a center of the fourth sheet 240.

A first end 241a of the fourth coil pattern 241 is disposed adjacent to the center of the fourth sheet 240. The first end 241a of the fourth coil pattern 241 is connected to the first end 231a of the third coil pattern 231 through the second via hole V2.

A second end 241b of the fourth coil pattern 241 is disposed to be aligned with a second edge of the fourth sheet 240, which is opposite to a first edge of the fourth sheet 240. Hence, the second end 241b of the fourth coil pattern 241 is exposed to the second side surface S2 of the filter stack 110.

The first via hole V1, spaced apart from the first end 241a of the fourth coil pattern 241, is formed in the fourth sheet 240. The first via hole V1 formed in the fourth sheet 240 connects the first via hole V1 formed in the third sheet 230 and the first end 241a of the fourth coil pattern 241.

The coil patterns and terminal patterns formed on the sheets constituting the electrode layer 200 may be modified into various shapes. Various modifications may be made to the electrode layer 200, including changes in the shape of the loops formed by the coil patterns and in the position where the ends are exposed. However, the stacking sequence of the first coil pattern 211, the second coil pattern 221, the third coil pattern 231, and the fourth coil pattern 241 is maintained as shown in the drawings.

The electrode layer 200 includes the first coil pattern 211, the second coil pattern 221, the third coil pattern 231, and the fourth coil pattern 241. Here, the first coil pattern 211 and the second coil pattern 221 form a first coil that constitutes the first channel. The third coil pattern 231 and the fourth coil pattern 241 form a second coil that constitutes the second channel.

Accordingly, in the multilayered common mode filter according to an embodiment of the present disclosure, a distance (spacing) between the coil patterns constituting each channel can remain constant, thereby allowing the resistance and inductance of the coil patterns constituting each channel to remain uniform.

The first capacitance layer 300a is configured as a stack in which a ground pattern and a plurality of capacitor patterns are formed. The first capacitance layer 300a is disposed over the electrode layer 200. The first capacitance layer 300a may be placed over the electrode layer 200 with the magnetic layer formed of ferrite or the like interposed therebetween. A magnetic layer formed of ferrite or the like may also be further placed over the first capacitance layer 300a.

The second capacitance layer 300b is configured as a stack in which a ground pattern and a plurality of capacitor patterns are formed. The second capacitance layer 300b is disposed under the electrode layer 200. The second capacitance layer 300b may be disposed under the electrode layer 200 with a magnetic layer formed of ferrite or the like interposed therebetween. A magnetic layer formed of ferrite or the like may also be further placed under the second capacitance layer 300b.

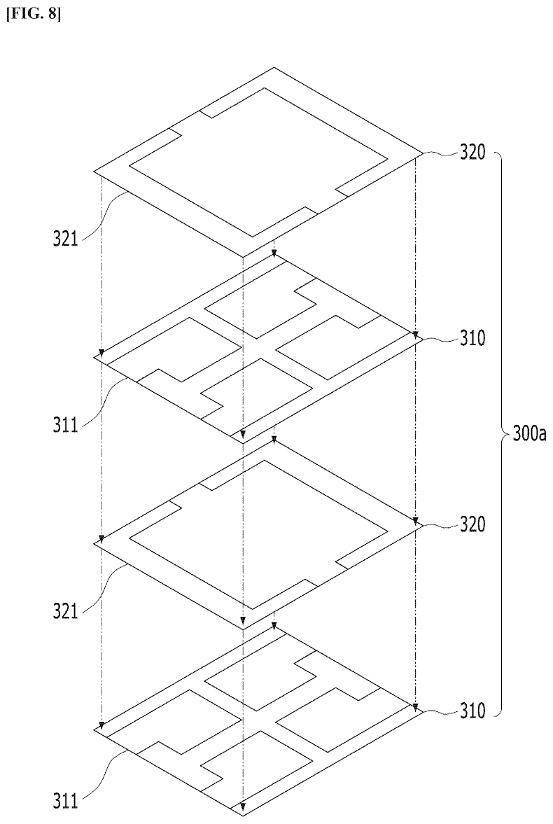

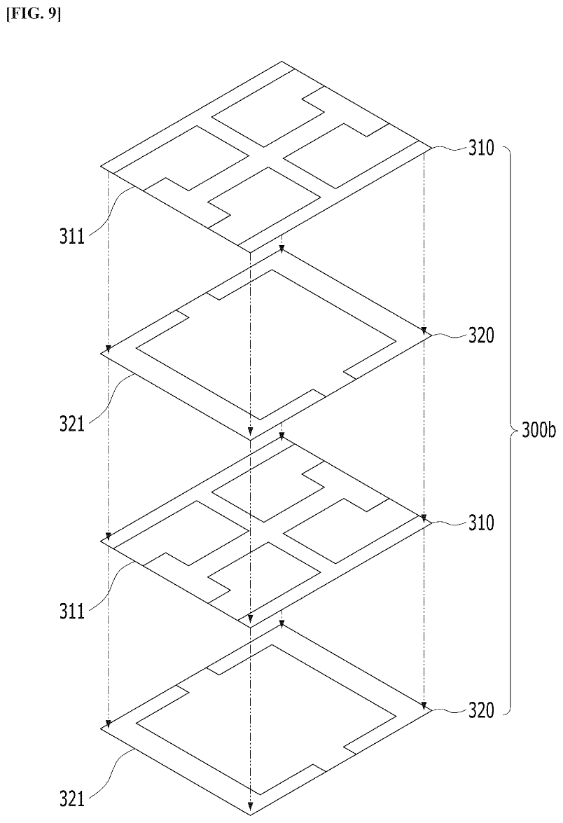

Referring to FIGS. 8 and 9, the first capacitance layer 300a and the second capacitance layer 300b may be configured in an SGSG stacking structure in which two fifth sheets 310, each having a plurality of capacitor patterns 311 formed thereof, and two sixth sheets 320, each having a ground pattern formed thereon, are alternately stacked.

The first capacitance layer 300a and the second capacitance layer 300b are symmetrically disposed with the electrode layer 200 interposed therebetween.

For example, referring to FIG. 8, the first capacitance layer 300a is configured such that one of the fifth sheets 310 is placed under one of the sixth sheets 320, a remaining one of the sixth sheets 320 is placed under the one of the fifth sheet 310, and a remaining one of the fifth sheets 310 is placed under the remaining one of the sixth sheets 320. Accordingly, the sixth sheet 320 is disposed at an uppermost portion of the first capacitance layer 300a, and the fifth sheet 310 is disposed at a lowermost portion of the first capacitance layer 300a.

Referring to FIG. 9, the second capacitance layer 300b is configured such that one of the sixth sheets 320 is placed under one of the fifth sheets 310, a remaining one of the fifth sheets 310 is placed under the one of the sixth sheets 320, and a remaining one of the sixth sheets 320 is placed under the remaining one of the fifth sheets 310. Accordingly, the fifth sheet 310 is disposed at an uppermost portion of the second capacitance layer 300b, and the sixth sheet 320 is disposed at a lowermost portion of the second capacitance layer 300b.

The plurality of capacitor patterns 311 are disposed on an upper surface of each fifth sheet 310. The plurality of capacitor patterns 311 are arranged to overlap the coil patterns included in the electrode layer 200. An additional capacitance is formed between the plurality of capacitor patterns 311 and the coil patterns.

Accordingly, the plurality of capacitor patterns 311 form an additional notch in the common mode attenuation characteristic, thereby expanding the attenuation band and allowing the multilayered common mode filter to have a broadband characteristic with an attenuation band in a range of approximately 1 GHz to 10 GHz.

The capacitor patterns 311 include a plurality of patterns disposed on an input terminal and an output terminal of the multilayered common mode filter.

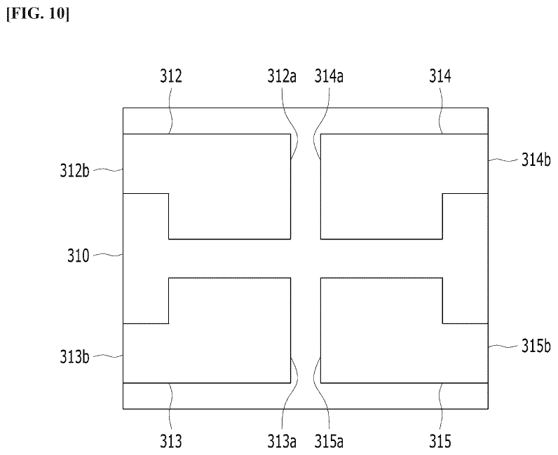

For example, referring to FIG. 10, a first capacitor pattern 312, a second capacitor pattern 313, a third capacitor pattern 314, and a fourth capacitor pattern 315 are formed on the fifth sheet 310.

The first capacitor pattern 312 and the second capacitor pattern 313 are disposed on the input terminal of the multilayered common mode filter (i.e., on the first side surface S1 of the filter stack 110). The third capacitor pattern 314 and the fourth capacitor pattern 315 are disposed on the output terminal of the multilayered common mode filter (i.e., on the second side surface S2 of the filter stack 110).

The first capacitor pattern 312 is disposed on an upper surface of the fifth sheet 310. A first end 312a of the first capacitor pattern 312 is located adjacent to a center of the fifth sheet 310. A second end 312b of the first capacitor pattern 312 is disposed to be aligned with a first edge of the fifth sheet 310. Hence, the first capacitor pattern 312 is exposed to the first side surface S1 of the filter stack 110.

The second capacitor pattern 313 is disposed on the upper surface of the fifth sheet 310 so as to be spaced apart from the first capacitor pattern 312. A first end 313a of the second capacitor pattern 313 is disposed adjacent to the center of the fifth sheet 310. A second end 313b of the second capacitor pattern 313 is disposed to be aligned with the first edge of the fifth sheet 310. Accordingly, the second capacitor pattern 313 is exposed to the first side surface S1 of the filter stack 110.

The third capacitor pattern 314 is disposed on the upper surface of the fifth sheet 310. A first end 314a of the third capacitor pattern 314 is disposed adjacent to the center of the fifth sheet 310 and is positioned to face the first end 312a of the first capacitor pattern 312. A second end 314b of the third capacitor pattern 314 is disposed to be aligned with a second edge of the fifth sheet 310. Accordingly, the third capacitor pattern 314 is exposed to the second side surface S2 of the filter stack 110.

The fourth capacitor pattern 315 is disposed on an upper surface of the fifth sheet 310 so as to be spaced apart from the third capacitor pattern 314. A first end 315a of the fourth capacitor pattern 315 is disposed adjacent to the center of the fifth sheet 310 and is positioned to face the first end 313a of the second capacitor pattern 313. A second end 315b of the fourth capacitor pattern 315 is disposed to be aligned with the second edge of the fifth sheet 310. Accordingly, the fourth capacitor pattern 315 is exposed to the second side surface S2 of the filter stack 110.

Alternatively, the capacitor patterns 311 may also be configured such that the third capacitor pattern 314 and the fourth capacitor pattern 315 are exposed to the input terminal of the multilayered common mode filter (i.e., to the first side surface S1 of the filter stack 110), and the first capacitor pattern 312 and the second capacitor pattern 313 are exposed to the output terminal of the multilayered common mode filter (i.e., to the second side surface of the filter stack 110).

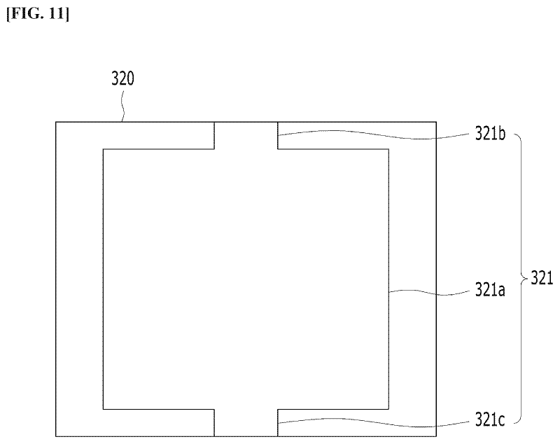

Referring to FIG. 11, a ground pattern 321 is disposed on the sixth sheet 320. The ground pattern 321 is disposed on an upper surface of the sixth sheet 320. The ground pattern 321 may include a first pattern 321a, a second pattern 321b, and a third pattern 321c.

The first pattern 321a may be formed in a plate shape and disposed at a center of the upper surface of the sixth sheet 320, and may be formed as an island pattern spaced apart from four edges of the sixth sheet 320.

The second pattern 321b extends from a third edge of the first pattern 321a and is disposed to be aligned with a third edge of the sixth sheet 320. In other words, a first end of the second pattern 321b is connected to the third edge of the first pattern 321a, and a second end of the second pattern 321b is disposed to be aligned with the third edge of the sixth sheet 320.

The third pattern 321c extends from a fourth edge of the first pattern 321a and is disposed to be aligned with a fourth edge of the sixth sheet 320. In other words, a first end of the third pattern 321c is connected to the fourth edge of the first pattern 321a, and a second end of the third pattern 321c is disposed to be aligned with the fourth edge of the sixth sheet 320.

Accordingly, the second pattern 321b and the third pattern 321c form a symmetrical shape with the first pattern 321a interposed therebetween, and the ground pattern 321 is exposed to a third side surface S3 and a fourth side surface S4 of the filter stack 110.

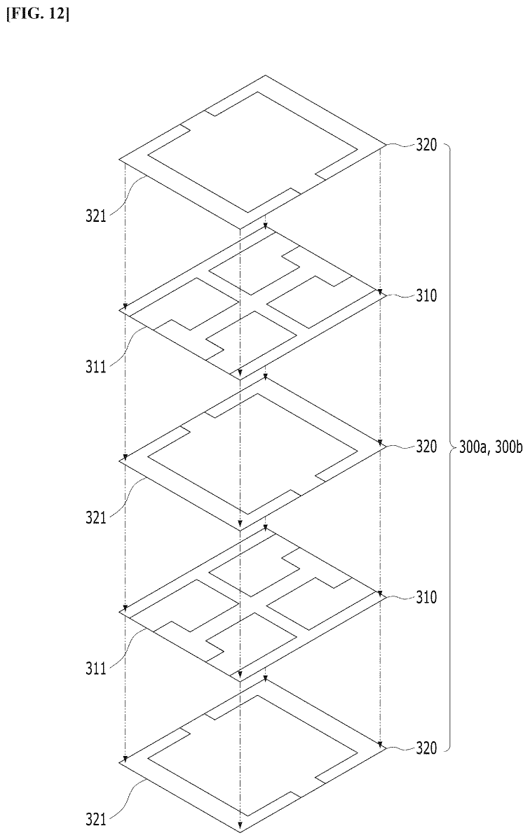

Referring to FIG. 12, the first capacitance layer 300a and the second capacitance layer 300b may each be configured in a GSGSG stacking structure in which two fifth sheets 310, each having a plurality of capacitor patterns 311 formed thereon, and three sixth sheets 320, each having a ground pattern 321 formed thereon, are alternately stacked. In other words, each capacitance layer 300 may be configured such that three sixth sheets 320 are sequentially stacked, and one fifth sheet 310 is interposed between every two adjacent sixth sheets 320. In this case, the first capacitance layer 300a and the second capacitance layer 300b are configured to be symmetrical with the filter stack 110 interposed therebetween.

An additional pole of the multilayered common mode filter is adjusted in position by capacitance. Accordingly, the numbers, shapes, and arrangement positions of the ground pattern 321 and the capacitor patterns 311 included in the first capacitance layer 300a and the second capacitance layer 300b may vary depending on the position of the additional pole.

The multilayered common mode filter according to an embodiment of the present disclosure may be configured as a multilayered common mode filter including a capacitance layer in which two ground sheets and two capacitance sheets are stacked (in the SGSG structure), or as a multilayered common mode filter including a capacitance layer in which three ground sheets and two capacitance sheets are stacked (in the GSGSG structure). Here, the ground sheet corresponds to the sixth sheet 320, and the capacitance sheet corresponds to the fifth sheet 310.

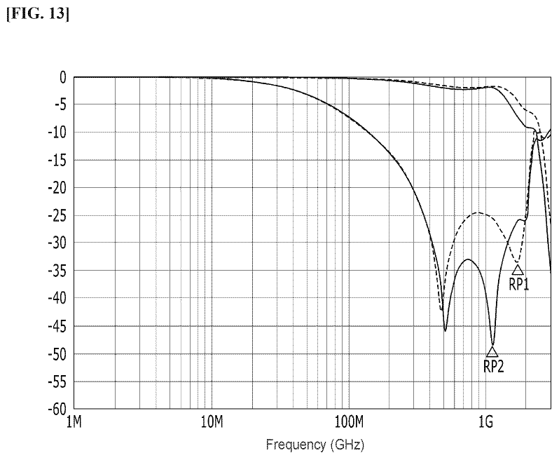

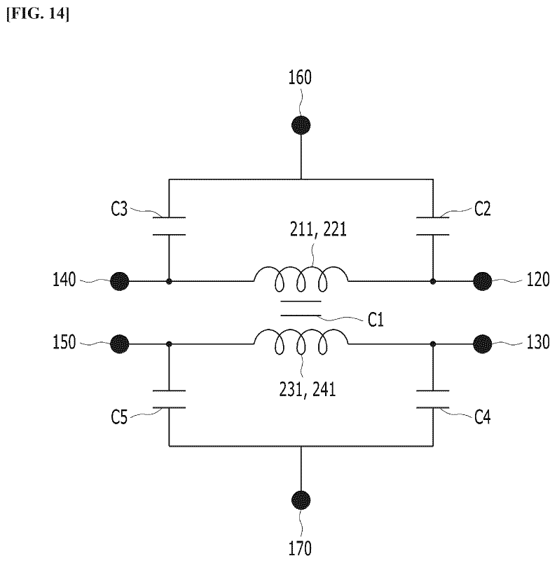

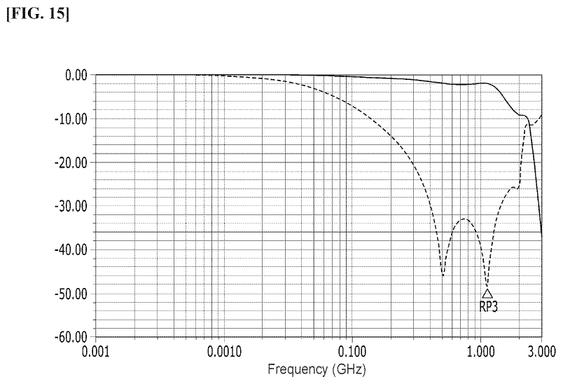

Referring to FIG. 13, in the multilayered common mode filter (having the SGSG structure or GSGSG structure) according to an embodiment of the present disclosure, an insertion loss (Sdd21) in a differential mode is −3 dB or greater in a frequency band of approximately 100 MHz or higher, and a common mode attenuation (Scc21) remains approximately −10 dB or less in a frequency band of approximately 100 MHz or higher.

A secondary resonance point RP1 of the multilayered common mode filter having the SGSG structure is formed at a first frequency higher than 1 GHz, and a secondary resonance point RP2 of the multilayered common mode filter having the GSGSG structure is formed at a second frequency that is higher than 1 GHz and lower than the first frequency.

Therefore, it can be understood that the secondary resonance point of the multilayered common mode filter shifts to a relatively lower frequency when capacitor patterns and/or ground patterns are added to the capacitance layers 300a and 300b, and shifts to a relatively higher frequency when the numbers of capacitor patterns and/or ground patterns are reduced.

Accordingly, the multilayered common mode filter according to an embodiment of the present disclosure allows a filter band required by a product to be modified by adjusting the number (or the number of stacked layers) of capacitor patterns and ground patterns constituting the capacitance layers 300a and 300b.

A first external electrode 120 is disposed on the second side surface of the filter stack 110. The first external electrode 120 is positioned adjacent to the third side surface of the filter stack 110. The first external electrode 120 is connected to the second end 211b of the first coil pattern 211 and the second ends 314b of the third capacitor patterns 314, which are exposed to the second side surface of the filter stack 110. Opposite ends of the first external electrode 120 may be formed to extend to an upper surface and a lower surface of the filter stack 110.

A second external electrode 130 is disposed on the second side surface of the filter stack 110. The second external electrode 130 is positioned adjacent to the fourth side surface of the filter stack 110. The second external electrode 130 is connected to the second end 241b of the fourth coil pattern 241 and the second end 315b of the fourth capacitor pattern 315, which are exposed to the second side surface of the filter stack 110. Opposite ends of the second external electrode 130 may be formed to extend to the upper surface and the lower surface of the filter stack 110.

A third external electrode 140 is disposed on the first side surface of the filter stack 110. The third external electrode 140 is positioned adjacent to the third side surface of the filter stack 110. The third external electrode 140 is connected to the second end 221b of the second coil pattern 221 and the second end 312b of the first capacitor pattern 312, which are exposed to the first side surface of the filter stack 110. Opposite ends of the third external electrode 140 may be formed to extend to the upper surface and the lower surface of the filter stack 110.

A fourth external electrode 150 is disposed on the first side surface of the filter stack 110. The fourth external electrode 150 is positioned adjacent to the fourth side surface of the filter stack 110. The fourth external electrode 150 is connected to the second end 231b of the third coil pattern 231 and the second end 313b of the second capacitor pattern 313, which are exposed to the first side surface of the filter stack 110. Opposite ends of the fourth external electrode 150 may be formed to extend to the upper surface and the lower surface of the filter stack 110.

A fifth external electrode 160 is disposed on the third side surface of the filter stack 110. The fifth external electrode 160 is connected to the second pattern 321b of the ground pattern 321, which is exposed to the third side surface of the filter stack 110. Opposite ends of the fifth external electrode 160 may be formed to extend to the upper surface and the lower surface of the filter stack 110.

A sixth external electrode 170 is disposed on the fourth side surface of the filter stack 110. The sixth external electrode 170 is connected to the third pattern 321c of the ground pattern 321, which is exposed on the fourth side surface of the filter stack 110. Opposite ends of the sixth external electrode 170 may be formed to extend to the upper surface and the lower surface of the filter stack 110.

The first external electrode 120 and the third external electrode 140 operate as an input terminal and an output terminal of the first channel, which is formed by the first coil pattern 211 and the second coil pattern 221. The second external electrode 130 and the fourth external electrode 150 operate as an input terminal and an output terminal of the second channel, which is formed by the third coil pattern 231 and the fourth coil pattern 241.

Referring to FIG. 14, in the multilayered common mode filter according to an embodiment of the present disclosure, a capacitance C1 is formed between the first coil (that is, the first coil pattern 211 and the second coil pattern 221) and the second coil (that is, the third coil pattern 231 and the fourth coil pattern 241).

In the multilayered common mode filter according to an embodiment of the present disclosure, since the first capacitance layer 300a and the second capacitance layer 300b are respectively disposed over and under the electrode layer 200, additional capacitances C2 and C3 are formed by a coupling effect between the first coil (211 and 221) and the capacitor patterns 521, and additional capacitances C4 and C5 are formed by a coupling effect between the second coil (231 and 241) and the capacitor patterns 521.

Accordingly, since additional capacitance is formed between each coil and the capacitor patterns 521, the capacitance of the multilayered common mode filter according to an embodiment of the present disclosure can be increased without adding an electrode layer including a sheet layer on which a coil pattern is formed.

Referring to FIG. 15, in the multilayered common mode filter according to an embodiment of the present disclosure, as additional capacitance is formed between the coils and the capacitor patterns 521, an additional notch may be formed in the common mode attenuation characteristic, thereby forming a secondary resonance point RP3. As the attenuation band is expanded by forming the second resonance point RP3, a broadband characteristic can be implemented.

In addition, in the multilayered common mode filter according to an embodiment of the present disclosure, as additional capacitance is formed between the coils and the capacitor patterns 521, degradation of differential mode insertion loss in the attenuation band can be prevented.

The above description is merely a description of the technical spirit of the present disclosure, and those skilled in the art may change and modify the present disclosure in various ways without departing from the essential characteristic of the present disclosure. Accordingly, the embodiments described in the present disclosure should not be construed as limiting the technical spirit of the present disclosure, but should be construed as describing the technical spirit of the present disclosure. The technical spirit of the present disclosure is not restricted by the embodiments. The range of protection of the present disclosure should be construed based on the following claims, and all of technical spirits within an equivalent range of the present disclosure should be construed as being included in the scope of rights of the present disclosure.

1. A multilayered common mode filter comprising a filter stack formed by stacking an electrode layer, a first capacitance layer, and a second capacitance layer, the filter stack including an upper surface, a lower surface, a first side surface, a second side surface opposite to the first side surface, a third side surface, and a fourth side surface opposite to the third side surface,
wherein the electrode layer comprises a stack provided with a plurality of coil patterns,
wherein the first capacitance layer comprises a stack provided with a capacitor pattern and a ground pattern, and is disposed over the electrode layer,
wherein the second capacitance layer comprises a stack provided with a capacitor pattern and a ground pattern, and is disposed under the electrode layer, and
wherein the first capacitance layer and the second capacitance layer are each configured such that the capacitor pattern overlaps at least one of the plurality of coil patterns and forms an additional capacitance.

2. The multilayered common mode filter of claim 1, wherein the electrode layer comprises:
a first sheet;
a first coil pattern disposed on a first surface of the first sheet;
a second sheet disposed under the first sheet;
a second coil pattern disposed on a first surface of the second sheet;
a third sheet interposed between the first sheet and the second sheet;
a third coil pattern disposed on a first surface of the third sheet;
a fourth sheet interposed between the second sheet and the third sheet; and
a fourth coil pattern disposed on a first surface of the fourth sheet.

3. The multilayered common mode filter of claim 2,
wherein a first end of the first coil pattern is connected to a first end of the second coil pattern through a first via hole, and a second end of the first coil pattern is exposed to the second side surface of the filter stack, and
wherein the first end of the second coil pattern is connected to the first end of the first coil pattern through the first via hole, and a second end of the second coil pattern is exposed to the first side surface of the filter stack opposite to one side surface of the filter stack.

4. The multilayered common mode filter of claim 2,
wherein a first end of the third coil pattern is connected to a first end of the fourth coil pattern through a second via hole, and a second end of the third coil pattern is exposed to the first side surface of the filter stack, and
wherein the first end of the fourth coil pattern is connected to the first end of the first coil through the first via hole, and a second end of the fourth coil pattern is exposed to the second side surface of the filter stack opposite to the first side surface of the filter stack.

5. The multilayered common mode filter of claim 2,
wherein a first end of the first coil pattern is connected to a first end of the second coil pattern through a first via hole passing through the first sheet, the third sheet, and the fourth sheet, and
wherein the first coil pattern and the second coil pattern are connected through the first via hole and form a first coil forming a first channel.

6. The multilayered common mode filter of claim 2,
wherein a first end of the third coil pattern is connected to a first end of the fourth coil pattern through a second via hole passing through the third sheet, and
wherein the third coil pattern and the fourth coil pattern are connected through the second via hole and form a second coil forming a second channel.

7. The multilayered common mode filter of claim 1, wherein the capacitor pattern and the ground pattern of the first capacitance layer are configured to be symmetrical with the capacitor pattern and the ground pattern of the second capacitance layer with the electrode layer interposed therebetween.

8. The multilayered common mode filter of claim 1,
wherein the first capacitance layer and the second capacitance layer are each configured as a stack formed by alternately stacking N fifth sheets and N sixth sheets,
wherein a plurality of capacitor patterns are disposed on each of the fifth sheets, and
wherein a ground pattern is disposed on each of the sixth sheets.

9. The multilayered common mode filter of claim 8,
wherein the first capacitance layer is configured such that the six sheets are stacked over the fifth sheets, so that one of the six sheets is disposed at an uppermost portion of the first capacitance layer, and one of the fifth sheets is disposed at a lowermost portion of the first capacitance layer, and
wherein the second capacitance layer is configured such that the fifth sheets are stacked over the sixth sheets, so that one of the fifth sheets is disposed at an uppermost portion of the second capacitance layer, and one of the sixth sheets is disposed at a lowermost portion of the second capacitance layer.

10. The multilayered common mode filter of claim 1,
wherein the first capacitance layer and the second capacitance layer are each configured as a stack formed by alternately stacking N fifth sheets and N+1 sixth sheets,
wherein a plurality of capacitor patterns are disposed on each of the fifth sheets, and
wherein a ground pattern is disposed on each of the sixth sheets.

11. The multilayered common mode filter of claim 10,
wherein the first capacitance layer and the second capacitance layer are each configured such that one of the fifth sheets is interposed between every two adjacent ones of the sixth sheets, and
wherein one of the sixth sheets is disposed at both an uppermost portion and a lowermost portion of each of the first capacitance layer and the second capacitance layer.

12. The multilayered common mode filter of claim 1,
wherein the capacitor pattern comprises:
a first capacitor pattern disposed on a first surface of a fifth sheet;
a second capacitor pattern disposed on the first surface of the fifth sheet, and disposed to be spaced apart from the first capacitor pattern;
a third capacitor pattern disposed on the first surface of the fifth sheet, and disposed to be spaced apart from the first capacitor pattern and the second capacitor pattern; and
a fourth capacitor pattern disposed on the first surface of the fifth sheet, and disposed to be spaced apart from the first to third capacitor patterns,
wherein a first end of the first capacitor pattern is disposed to face a first end of the third capacitor pattern, and
wherein a first end of the second capacitor pattern is disposed to face a first end of the fourth capacitor pattern.

13. The multilayered common mode filter of claim 12,
wherein a second end of the first capacitor pattern and a second end of the second capacitor pattern are exposed to the first side surface of the filter stack, and
wherein a second end of the third capacitor pattern and a second end of the fourth capacitor pattern are exposed to the second side surface of the filter stack.

14. The multilayered common mode filter of claim 1,
wherein the ground pattern comprises:
a first pattern having a planar shape and disposed on a first surface of a sixth sheet;
a second pattern disposed on the first surface of the sixth sheet; and
a third pattern disposed on the first surface of the sixth sheet,
wherein a first end of the second pattern is connected to one edge of the first pattern, and a second end of the second pattern is exposed to the third side surface of the filter stack, and
wherein a first end of the third pattern is connected to another edge of the first pattern opposite to the one edge of the first pattern, and a second end of the third pattern is exposed to the fourth side surface of the filter stack.

15. The multilayered common mode filter of claim 1, further comprising:
a first external electrode disposed on the second side surface of the filter stack opposite to the first side surface of the filter stack, and connected to a first coil pattern exposed to the second side surface of the filter stack;
a second external electrode disposed on the second side surface of the filter stack, and connected to a fourth coil pattern exposed to the second side surface of the filter stack;
a third external electrode disposed on the first side surface of the filter stack, and connected to a second coil pattern exposed to the first side surface of the filter stack; and
a fourth external electrode disposed on the first side surface of the filter stack, and connected to a third coil pattern exposed to the first side surface of the filter stack.

16. The multilayered common mode filter of claim 15,
wherein the first external electrode is further connected to a third capacitor pattern exposed to the second side surface of the filter stack,
wherein the second external electrode is further connected to a fourth capacitor pattern exposed to the second side surface of the filter stack,
wherein the third external electrode is further connected to a first capacitor pattern exposed to the first side surface of the filter stack, and
wherein the fourth external electrode is further connected to a second capacitor pattern exposed to the first side surface of the filter stack.

17. The multilayered common mode filter of claim 15, further comprising:
a fifth external electrode disposed on the third side surface of the filter stack, and connected to a second pattern of the ground pattern, the second pattern being exposed to the third side surface of the filter stack; and
a sixth external electrode disposed on the fourth side surface of the filter stack opposite to the third side surface of the filter stack, and connected to a third pattern of the ground pattern, the third pattern being exposed to the fourth side surface of the filter stack
